(19) United States
(12) Patent Application Publication
(10) Pub. No.: US 2010/0059755 A1
(43) Pub. Date: Mar. 11, 2010

(54) IMPROVED OXIDE-BASED FIELD-EFFECT TRANSISTORS

(75) Inventors: Thomas Anthopoulos, London (GB); Donal Donat Conor Bradley, Buckinghamshire (GB); Saif Ahmed Haque, Middlesex (GB)

Correspondence Address: Kirschstein, Israel, Schiffmiller & Pieroni, P.C., 425 FIFTH AVENUE, 5TH FLOOR, NEW YORK, NY, 10016-2223, US

(73) Assignee: IMPERIAL INNOVATIONS LIMITED, London (GB)

(21) Appl. No.: 12/595,305

(22) PCT Filed: Apr. 11, 2008
(86) PCT No.: PCT/GB08/01298

§ 371 Date: Oct. 9, 2009

(30) Foreign Application Priority Data
Apr. 20, 2007 (GB) 0707714.2

(51) Int. Cl. H01L 29/786; H01L 21/336

(52) U.S. Cl. 257/59; 257/57; 438/151; 257/E21.411; 257/E29.273

(57) ABSTRACT

A field-effect transistor includes a source region; a drain region; a semiconductor layer disposed between the source and drain regions; a gate region; and a dielectric region disposed between the semiconductor layer and the gate region. The semiconductor layer comprises a titanium dioxide film. The transistor may be light sending, gas- or bio-sensing, or used in a visual display or in electronic circuits. The transistor is formed by forming a dielectric layer adjacent a gate region; forming a source region and a drain region; and forming a semiconductor layer on the dielectric layer, the semiconductor layer comprising titanium dioxide. The titanium dioxide semiconductor layer may be deposited by spray pyrolysis, or alternatively mesoporous TiO₂ films of nanocrystalline morphology may be formed by spin coating, doctor-blading or screen-printing techniques.

This invention relates to oxide-based field-effect transistors. It is particularly applicable, but by no means limited, to thin-film transistors.

### BACKGROUND TO THE INVENTION

Semiconducting thin-film transistors (TFTs) comprise a substrate, a semiconducting layer, a dielectric layer, and conducting materials for the source, drain and gate electrodes. Depending on the gate potential (V_{G}) and the drain potential (V_{D}), the channel current (i.e. the current flowing from the source electrode to the drain electrode, often referred to as I_{D}) can be modulated. Such TFTs are used in applications such as pixel engine and integrated drivers in active matrix flexible displays, integrated microelectronic circuits, and many other applications that will be familiar to those skilled in the art.

Depending on the application, an inorganic or organic material can be employed as the semiconductor layer. For example, organic materials have the potential for flexible large-area devices and low manufacturing costs, since they can be deposited using solution processing techniques. Despite this advantage, however, the performance of most organic semiconductors is only moderate and is not yet suitable for practical applications. On the other hand, traditional high-performance inorganic semiconductors such as silicon and germanium require highly controlled growth techniques that give rise to relatively high overall manufacturing costs, while their potential applications are limited due to their poor mechanical flexibility and the demanding processing required during fabrication.

There is a desire for a combination of the attractive processing properties of organic semiconductors with the high performance characteristics of inorganic semiconductors.

### SUMMARY OF THE INVENTION

According to a first aspect of the present invention there is provided a field-effect transistor as defined in claim 1 of the appended claims. Thus there is provided a field-effect transistor comprising: a source region; a drain region; a semiconductor layer disposed between the source and drain regions; a gate region; and a dielectric region disposed between the semiconductor layer and the gate region; wherein the semiconductor layer comprises a titanium dioxide (TiO₂) film.

The term “between”, in the context of “the semiconductor layer disposed between the source and drain regions”, should be interpreted broadly, to encompass both spatially between (i.e. physically located between the source and the drain regions) and also functionally between (i.e. arranged to form a semiconducting channel from the source to the drain via the semiconductor layer).

By forming the semiconductor layer as a TiO₂ film, this provides the advantage that the semiconductor layer may be fabricated using a solution processing technique, such as spray pyrolysis, or by spin coating, doctor-blading or screen-printing. This circumvents the problem of expensive manufacturing typically required for the deposition of inorganic semiconductors such as silicon and germanium, etc. The TiO₂ semiconductor layer may also be deposited on a flexible substrate, to form a flexible device. We have also unexpectedly found from our experiments that transistors having a TiO₂ semiconductor layer exhibit light sensitivity, without the need for an organic layer to act as an optical sensitizer. Furthermore, TiO₂ is biocompatible, hence making it a good candidate for use in electronic or optoelectronic circuits for biomedical applications.

With all the aspects of the invention, preferable, optional, features are defined in the dependent claims.

Thus, the semiconductor layer may be substantially dense, and/or may be mesoporous. As those skilled in the art will appreciate, a mesoporous material is a material containing pores with diameters between about 2 nm and 50 nm.

An organic dye/semiconductor layer may be disposed adjacent to the titanium dioxide semiconductor layer. This may be beneficial (although not necessary) if the transistor is to be used in light-sensing applications. The organic semiconductor could be polymers, oligomers, small molecules, co-polymers, dendrimers etc. Alternatively, a mesoporous titanium dioxide semiconductor layer may be coated with a layer of dye molecules to act as an optical sensitizer, and infiltrated with a molecular hole transporting organic semiconductor.

Alternatively, the semiconductor layer may further comprise molecular adsorbates, such as dye pigments or protein molecules, to enable the transistor to be used for sensing gas or biological molecules. Receptors may be provided on the surface of the semiconductor layer to enhance reaction between the semiconductor layer and gas or biological molecules.

According to a further aspect of the invention there is provided a method of forming a field-effect transistor comprising: forming a dielectric layer adjacent a gate; forming a source region and a drain region; and forming a semiconductor layer on the dielectric layer, the semiconductor layer comprising titanium dioxide.

The semiconductor layer may be fabricated using a solution processing technique, such as by spray pyrolysis using a precursor solution, or by spin coating, doctor-blading or screen-printing using a sol-gel colloidal suspension. These techniques enable the transistor to be fabricated relatively inexpensively, and also enable the semiconductor layer to be deposited on a flexible substrate if it is desired to form a flexible device. Spray pyrolysis in particular may be used to form a substantially dense titanium dioxide semiconductor layer with enhanced transport characteristics, i.e. high charge mobility.

### BRIEF DESCRIPTION OF THE DRAWINGS

Embodiments of the invention will now be described, by way of example only, and with reference to the drawings in which:

FIG. 1 illustrates a bottom-gate bottom-contact, TFT architecture according to an embodiment of the invention;

FIG. 2 illustrates a sequence of steps in the production of a bottom-gate bottom-contact TFT according to an embodiment of the invention;

FIG. 3 illustrates a deposition process using a spray pyrolysis technique;

FIG. 4 illustrates experimentally-measured transfer curves for a TiO₂-based bottom-gate bottom-contact FET according to an embodiment of the invention, with L and W defining the channel length and width respectively;

FIG. 5 illustrates different TFT architectures according to embodiments of the invention, namely (a) a bottom-gate top-contact TFT, (b) a top-gate top-contact TFT, (c) a top-gate bottom-contact TFT, (d) a top-gate TFT with asymmetric source-drain contacts, and (e) a double gate TFT;

FIG. 6 illustrates (a) the architecture of a TiO₂-based bottom-gate top-contact transistor structure according to an embodiment of the invention, (b) experimentally-measured output characteristics from such a TFT with L=60 μm and W=1 mm, employing aluminium source and drain electrodes, and (c) experimentally-measured transfer characteristics for the same transistor at room temperature;

FIG. 7 illustrates experimentally-measured (a) electron mobility values and (b) current on/off ratio values, in both cases showing their dependence on exposure time to ambient air;

FIG. 8 illustrates (a) a bilayer type phototransistor based on TiO₂ and a organic semiconductor (polymer or small molecule), (b) a bilayer type TFT comprising a dense TiO₂ film and a porous TiO₂/organic dye-semiconductor layer, and (c) a single layer type FET; and

FIG. 9 illustrates experimentally-measured transfer characteristics of a TiO₂-based FET (L=40 μm, W=20 mm) obtained in the dark and under illumination with visible light.

### DETAILED DESCRIPTION OF PREFERRED EMBODIMENTS

The present embodiments represent the best ways known to the applicants of putting the invention into practice. However, they are not the only ways in which this can be achieved.

The present embodiments relate to the development of field-effect transistors based on films of titanium dioxide (TiO₂) fabricated using a solution processing technique, such as by spray pyrolysis. Our approach circumvents the problem of expensive manufacturing typically required for the deposition of inorganic semiconductors such as silicon, germanium, etc. Additionally, due to the attractive properties of TiO₂, a number of potential applications can be envisioned. Example applications include switching pixel engine and integrated drivers in active matrix flexible displays, bio-sensing FETs, and light-sensing FETs. To the best of our knowledge no field-effect transistor based on a TiO₂ film as the semiconductor has yet been reported in the open literature.

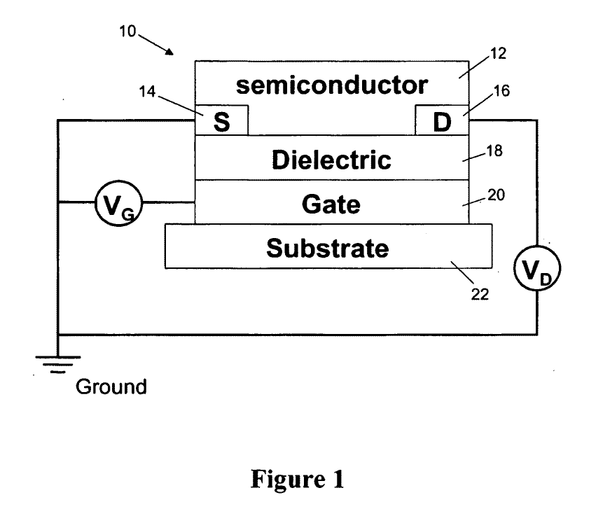

The present embodiments provide a TiO₂-based TFT device and some potential technological applications. As illustrated in FIG. 1, a basic TiO₂-based TFT device 10 consists of a semiconducting TiO₂ active layer 12 applied onto a three-terminal electrode architecture comprising a source electrode 14, a drain electrode 16 and a gate electrode 20. The gate electrode 20 is separated from the semiconductor layer 12 and the source and drain electrodes by a dielectric layer 18.

Preliminary experiments have been performed on devices employing gold source and drain electrodes 14, 16, highly doped silicon (Si⁺⁺) as the gate electrode 20, and silicon dioxide (SiO₂) as the gate dielectric 18.

The TiO₂ layer was deposited by spray pyrolysis onto the pre-fabricated transistor structure at 450° C. in oxygen, followed by a further annealing step at 500° C. for 30 minutes in ambient atmosphere. Alternative deposition and annealing temperatures in the range of 140-700° C. are also possible, preferably in the range of 250-600° C., and more preferably in the range of 400-500° C. We employ the spray pyrolysis technique as it provides dense films with enhanced transport characteristics, i.e. high charge mobility. Freshly prepared FETs were then transported into a glove-box for electrical characterization.

Fabrication of TiO₂-based TFT Devices

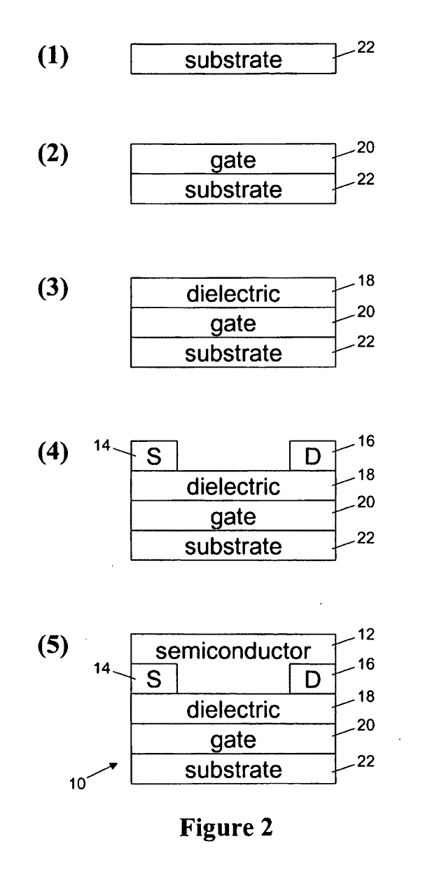

The device of FIG. 1 may be fabricated using the steps illustrated in FIG. 2, as follows:

Step (1): The substrate 22 may be rigid or flexible depending on the application. In the present embodiment highly conductive Si⁺⁺ is employed as the substrate 22, which also acts as the gate electrode 20, but this may be replaced by other materials.
Step (2): If the substrate 22 is not conducting then a conductive gate 20 has to be deposited. This can be a conductive polymer, metal, or any type of solid conductive substance (e.g. silicon, metal oxides, transparent metal oxides, etc). In the present embodiment the gate 20 is made using conductive doped silicon. However, flexible gates and substrates could also be used, made of metal foil or plastic, which would enable fabrication of flexible devices or arrays.

Step (3): The dielectric 18 is then deposited on the top of the gate 20. This is the standard process for a bottom-contact bottom-gate FET. In the present embodiment the dielectric is standard thermally-grown SiO₂. However this layer can be any inorganic material having good insulating properties, or similarly-performing organic materials (small molecules, oligomers and polymers).

Step (4): The source electrode 14 and the drain electrode 16 (“S” and “D”) are then deposited on top of the dielectric 18. In the present embodiment the source and drain electrodes 14, 16 are each made of chromium and gold layers, the chromium and gold layers having thicknesses of 10 nm and 100 nm respectively, which are vacuum deposited and patterned using standard photolithographic techniques. Here the chromium acts as an adhesion layer for the gold, since the latter will not stick to the SiO₂ by itself. The role of the thin chromium layer is therefore is not functional in terms of the electronic functionality of the device. However, other contact metals may alternatively be employed, as those skilled in the art will appreciate.

Step (5): Finally, the TiO₂ semiconductor layer 12 is formed on the top of the prefabricated structure. The TiO₂ semiconductor layer may be deposited using spray pyrolysis, which is a technique commonly used for the deposition of TiO₂, or may be formed as a mesoporous film of nanocrystalline morphology by spin coating, doctor-blading or screen-printing techniques. These alternative techniques for forming the TiO₂ semiconductor layer will now be described:

### (a) Deposition of TiO₂ Films by Spray Pyrolysis

Spray pyrolysis is a widely-used technique for TiO₂ thin film deposition. The advantage of this method is that it is relatively easy to scale up for large area production. There are several spraying methods to generate aerosols with droplet size in the micrometre to sub-micrometre range. In our work, experiments were performed with pneumatic pressure nozzles.

Spray pyrolysis is based on evaporation of a precursor in the vicinity of a substrate heated by a hotplate. With TiO₂ deposition, a temperature of 450° C. was used, although alternative deposition temperatures in the range of 140-700° C. are also possible, preferably in the range of 250-600° C., and more preferably in the range of 400-500° C. Aerosols have been widely used as the material source for the deposition of thin films. The advantages of using aerosols are relatively low equipment costs and wider options for precursor materials. Deposition can be achieved in an open atmosphere without the need for sophisticated equipment. Unlike CVD (Chemical Vapour Deposition) processes, precursor materials with high vapour pressure are not required in aerosol deposition. However, spray pyrolysis requires a large volume of carrier gas to deliver the aerosol onto the substrate during film deposition. The large flow of carrier gas may result in turbulence near the substrate, which may affect the efficiency of deposition and the uniformity of the resultant film, and so care should be taken to produce a well-defined uniform film.

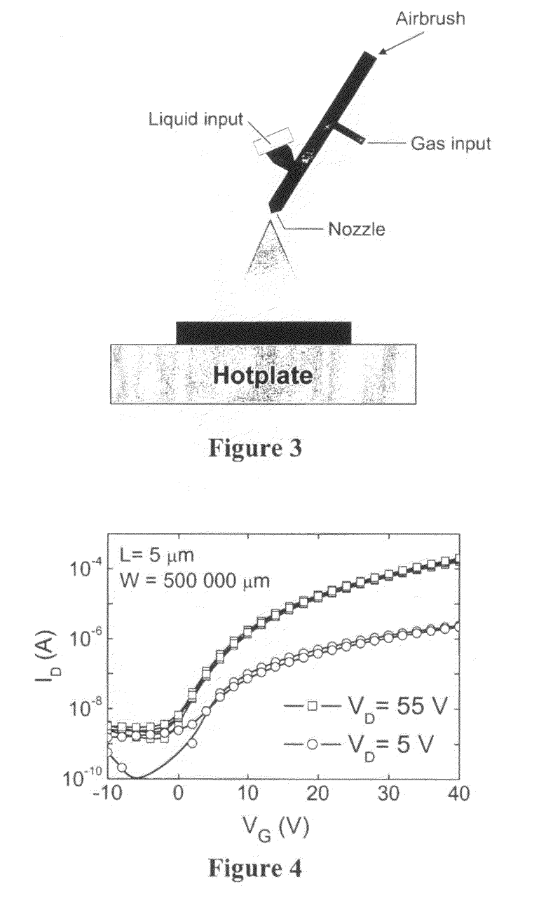

A TiO₂ film may be fabricated from a precursor solution containing titanium(IV) isopropoxide (Ti-iPr), 2,4 pentanedione (PD) in absolute ethanol with concentration of 5 vol. % at Ti-iPr:PD molar ratio of 1:2. The solution may be deposited employing a Badger airbrush system (as illustrated in FIG. 3) using nitrogen gas as a carrier gas, onto polished silicon dioxide substrates. As those skilled in the art will appreciate, alternative precursor solutions and carrier gases may also be used.

The TiO₂ film is preferably deposited at 450° C. by a pulsed solution feed. For example, the pulses may consist of 20 seconds of spray time followed by 20 seconds of pause, and five pulses may be performed. Other pulsed deposition procedures will be known to those skilled in the art. The film is subsequently heat treated for 30 minutes at 500° C. in air in order to remove any residual un-reacted precursor. Alternative deposition and heat treatment temperatures in the range of 140-700° C. are also possible, preferably in the range of 250-600° C., and more preferably in the range of 400-500° C.

With our TiO₂-based FETs, the deposited films on pre-patterned FET substrates were post-annealed under ambient atmosphere at 500° C. for 30 minutes. The TFT devices were then placed inside a glove-box, followed by annealing at 150° C. for several hours prior to electrical characterization.

### (b) Deposition of Mesoporous TiO₂ Films

Mesoporous TiO₂ films of nanocrystalline morphology may be prepared by spin coating, doctor-blading or screen-printing a TiO₂ paste consisting of 10 nm sized TiO₂ particles, this being prepared from a sol-gel colloidal suspension containing 12.5 wt % TiO₂ particles and 6.2 wt % Carbowax 20,000.

The TiO₂ nanoparticles may be synthesized by employing the following procedure: 20 ml of titanium iso-propoxide is injected into 5.5 g of glacial acetic acid under argon atmosphere and stirred for 10 minutes. The mixture is then injected into 120 ml of 0.1 M nitric acid under anhydrous atmosphere at room temperature in a conical flask and stirred vigorously. The flask is left uncovered and heated at 80° C. for 8 hours. After cooling, the solution is filtered using a 0.45 μm syringe filter, diluted to 5 wt % TiO₂ by the addition of H₂O and then autoclaved at 220° C. for 12 hours. The colloids are re-dispersed with a 60 s cycle burst from a LDU Soniprobe horn. The solution is then concentrated to 5% on a rotary evaporator using a membrane vacuum pump at a temperature of 40° C. Next, 6.2 wt % Carbowax 20,000 is added and the resulting paste is stirred slowly overnight to ensure homogeneity. Finally, an appropriate volume of this suspension is deposited onto the substrates. The resulting films are dried in air, and then sintered at 450° C. for 20 minutes in air. Alternative processing temperatures in the range of 140-700° C. are also possible, preferably in the range of 250-600° C., and more preferably in the range of 400-500° C.

Details of the synthesis of the TiO₂ particles and paste, for producing mesoporous TiO₂ films, are described in the following three papers:
C. J. Barbe et al., J. Am. Ceram. Soc. 1997, 80, 3157
E. Palomares et al., J. Am. Chem. Soc. 2003, 125, 475
S. A. Hague et al., Adv. Mater. 2007, 19, 683

### Electronic Applications

FIG. 4 illustrates the transfer characteristics for a bottom-gate bottom-contact TiO₂-based transistor measured in nitrogen (N₂) environment. The TFT device has a channel length from the source electrode to the drain electrode of 5 μm, and a channel width of 50 cm. The TiO₂ layer was formed by the spray pyrolysis technique described above. The channel current (I_{D}) flowing from the source electrode 12 to the drain electrode 14 was measured at values of gate voltage (V_{G}) ranging from −10 V to 40 V, for drain voltages (V_{D}) of 5 V and 55V. We find that the device current is due to the conduction of electrons through the channel. The transistor exhibits moderate electron mobilities with maximum values in the order of 2×10^{˜3} cm²/Vs. Despite this relatively low mobility, significant improvements are anticipated through routine optimization of the electrode materials and the device architecture. If the mobility of TiO₂ FETs can be increased to the order of 0.1 cm²/Vs, or higher, then the device performance will be comparable to FETs based on amorphous silicon. The latter FETs are employed in pixel engine and integrated drivers in active matrix optical displays such as liquid crystal displays (LCD) that can be found in many domestic applications including LCD-TVs, computer LCD monitors, LCD video projectors, and mobile phones.

### Alternative Device Architectures

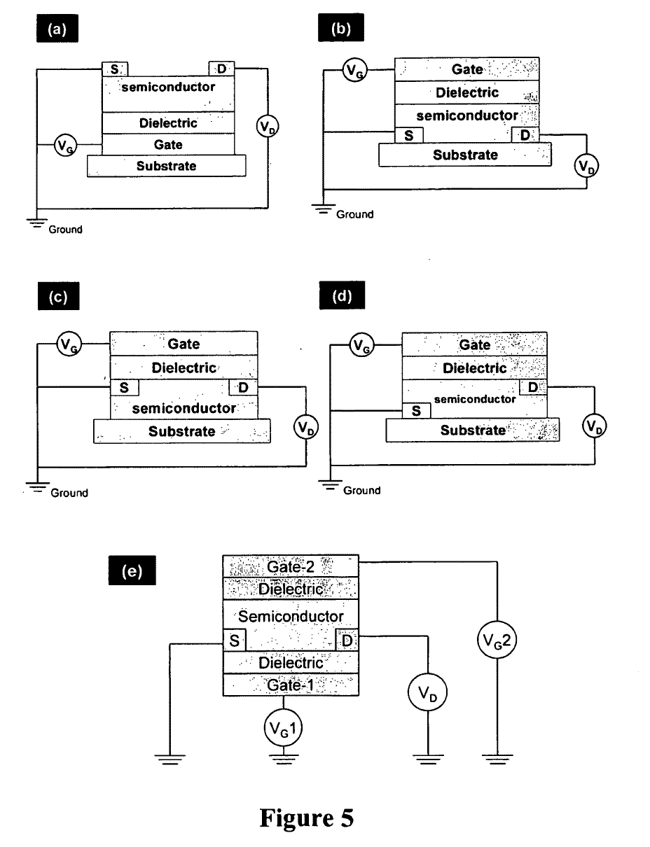

FIG. 1 shows the device structure for a bottom-gate bottom-contact TiO₂-based TFT, but alternative device architectures for TiO₂-based TFTs can be envisioned. Some examples are shown in FIG. 5, which illustrates (a) a bottom-gate top-contact TFT, (b) a top-gate top-contact TFT, (c) a top-gate bottom-contact TFT, (d) a top-gate TFT with asymmetric source-drain contacts, and (e) a double gate TFT. These different device architectures, in combination with different metal electrodes, may be exploited for performance enhancement of the TFT depending on the particular application. Other device architectures are also envisioned and will be familiar to those skilled in the art.

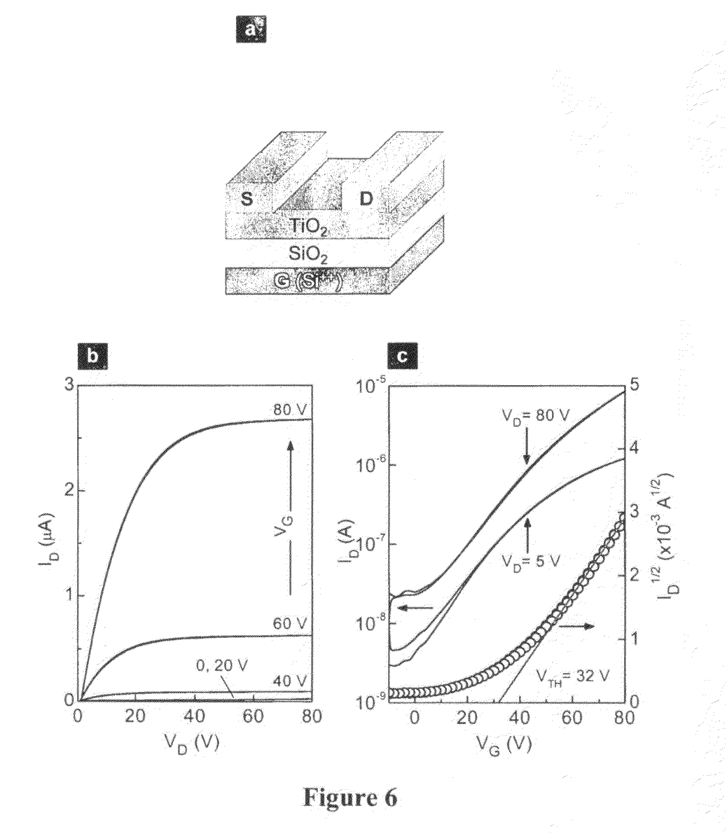

As well as making the bottom-gate bottom-contact transistor based on gold contact electrodes as described above, we have also fabricated TiO₂-based TFTs in a bottom-gate top-contact configuration as shown schematically in FIGS. 5a and 6a, using low work function electrodes such as aluminium. Not surprisingly, the carrier mobility of such transistors is found to increase and reach maximum values of 5×10⁻² cm²/Vs and an on/off current ratio of >10². The operating characteristics of this device (having a channel length of 60 μm and a channel width of 1 mm) are shown in FIGS. 6b and 6c. FIG. 6b shows the output characteristics and FIG. 6c shows the transfer characteristics measured at room temperature. The improved operation of this device (compared to the bottom-gate bottom-contact device of FIG. 4) is attributed to better electron injection due to the different contact configuration. Similar effects have been reported in the literature for organic transistors.

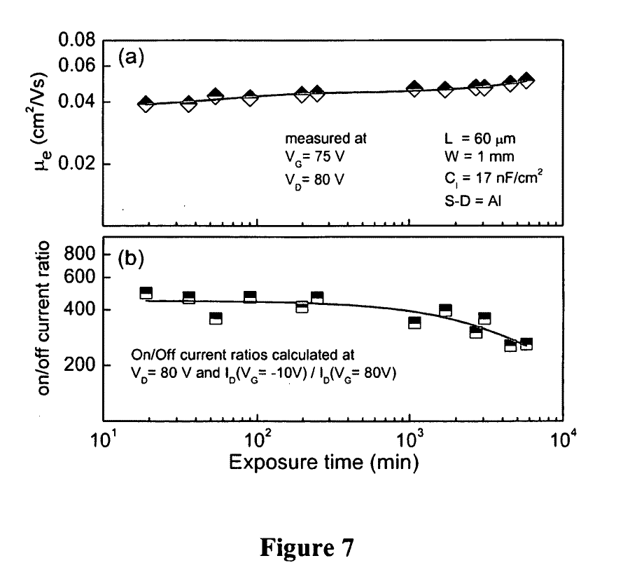

Our TiO₂-based transistors are also found to be relatively air stable. This is clearly evident from the experimental data displayed in FIG. 7, which shows the variation with exposure time of (a) electron mobility values and (b) on/off current ratio values, measured in an ambient atmosphere. Here stable electron transport at different exposure times to ambient air is observed. In fact there is slight increase in the electron mobility with exposure time. The exact mechanisms responsible for this increase are not known, but could be related to a number of mechanisms including gradual doping of the TiO₂ layer with oxygen. This doping effect could also be responsible for the observed reduction in the on/off ratio for prolonged (>10³ min) exposure of the sample to ambient air. Future work may reveal a different mechanism to be responsible for this behaviour.

Although the experimental results shown in FIG. 7 were obtained using a bottom-gate top-contact TiO₂-based transistor (as illustrated in FIG. 6a), similar results would be expected with other configurations of TiO₂-based transistors, since the stability properties are dependent on the materials used rather than the device architecture.

### Sensing Applications

Applications for TiO₂-based TFTs are envisioned in the area of light-sensing. For light-sensing applications, a dense or mesoporous (or a combination of both) film of TiO₂ may be employed, together with an organic dye/semiconductor as in the case of dye-sensitized solar cells. The conductivity of the TiO₂/dye can be altered by the intensity of the light incident on the surface due to free carrier photogeneration within the active layers. As a result the overall transistor current can be modulated (increased or decreased). Since dye-sensitized solar cells are highly efficient, a large response may be achieved.

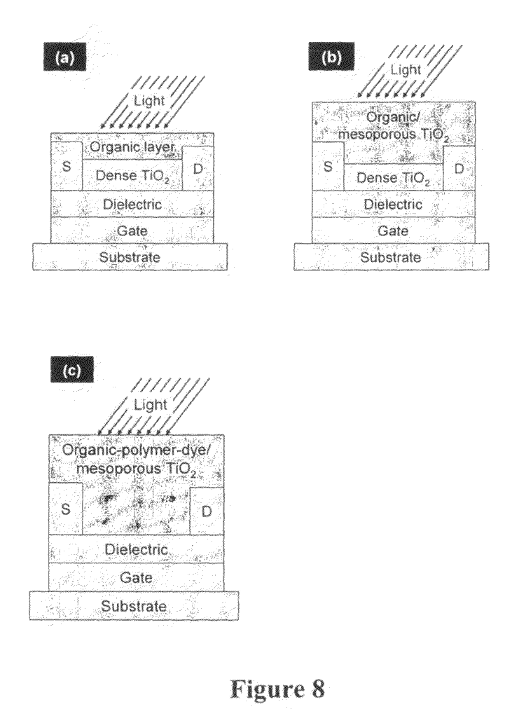

Photo-detecting TiO₂-based TFTs can be fabricated employing different device architectures broadly similar to those shown in FIGS. 1 and 5. However, to fabricate photosensitive TiO₂-based TFTs, a two layer semiconductor structure may be employed, comprising a layer of TiO₂ and an organic dye/semiconductor (polymer or small molecule). Schematic representations of three possible photo-detecting device architectures are shown in FIG. 8, in which structure (a) is a bilayer type phototransistor based on TiO₂ and an organic semiconductor (polymer or small molecule), and structure (b) is a bilayer type TFT comprising a dense TiO₂ film and a porous TiO₂/organic dye-semiconductor layer.

Structure (c) of FIG. 8 shows a single layer FET having a mesoporous layer of TiO₂ (which may be deposited as described above) coated with a monolayer of dye molecules to act as an optical sensitizer, and infiltrated with a molecular hole transporting organic semiconductor. The porous TiO₂ layer however could be infiltrated using only an organic semiconductor such as polymers, small molecules, co-polymers, dendrimers and others, acting both as the sensitizer and the hole transporting medium.

The role of the organic material is to absorb the light so formation of bound hole-electron pairs (excitons) is possible, and also to transport the photogenerated holes. These excitons will eventually dissociate under the influence of the built-in potential present at the interface between the TiO₂ and the organic material. The resulting free carriers (holes and electrons) will be transported to the collecting electrodes through the TiO₂ (electrons) and the organic material (holes), hence contributing to the overall current flowing through the transistor channel. This change in the operating characteristics of the device can then be detected electronically, i.e. the electrical signal.

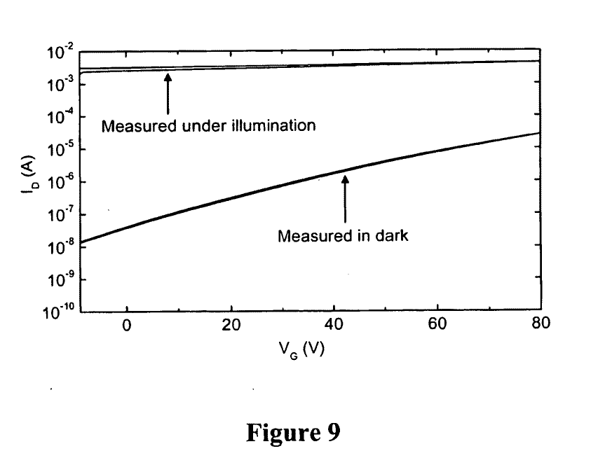

Although the use of organic material may be beneficial when fabricating photo-detecting TiO₂-based TFTs, our experiments have unexpectedly revealed that organic material is not necessary in order for TiO₂-based FETs to exhibit light sensitivity. Specifically, we have found that transistors having a TiO₂ semiconductor layer, with no organic layer or organic content, exhibit light sensitivity—without the need for an organic layer to act as an optical sensitizer. Our experiments investigated the sensitivity of TiO₂-based transistors to ultraviolet light. FIG. 9 shows the transfer characteristics of such a device measured in dark and under illumination with ultraviolet light. A clear increase in the channel current upon illumination is observed. Such a device could be used as an electro-optical transducer in numerous technological applications.

We also envision the use of TiO₂-based FETs in gas/bio-sensing applications. A key feature of the TiO₂ layer is that it can be functionalized with molecular adsorbates such as dye pigments and protein molecules. Such molecules can promote changes in the channel current (I_{D}) flowing through the FET device in response to a gaseous or biological analyte. Reaction between the TiO₂ and the analyte may be promoted through the incorporation of special receptors on the surface of the semiconductor layer. Since the channel profile, that is the distance from the dielectric to the surface of the semiconductor through which all channel current flows, may be only a few nanometers, a significant change in the operating characteristics of the device is expected and hence great signal enhancement capabilities may be realised. However, a number of different detection schemes can be envisioned including electro-optical methods.

Summary of Some Potential Applications for TiO₂-based FETs

### Electronic Applications:

An important advantage of TiO₂-based FETs lies in the solution processing properties of the TiO₂ layer and the low manufacturing cost associated with the solution processing technique. Another interesting feature of TiO₂ is its high optical transparency in the visible spectrum, thus making it suitable for application in transparent electronics.

### Display Applications:

An important advantage of TiO₂-based FETs lies in the solution processing properties of the TiO₂ layer and the low manufacturing cost associated with the solution processing technique. The ability to process TiO₂ in large areas provides a further advantage.

### Light-sensing Applications:

An important advantage of TiO₂-based FETs for light sensing-applications is the potentially high sensitivity of the devices. Combination with electro-optical detection of bio-molecules is also envisioned.

### Gas/bio-sensing Applications:

The TiO₂-based FET approach offers the potential for ease of fabrication, signal enhancement, stability, and the possibility of surface chemistry. The unique operating principle of the TiO₂-based FET may be suitable for detection at low concentrations, even at ultra low levels. In addition TiO₂ offers chemical reactions suitable for surface modification covalently. This is highly desirable for linking specific atoms/molecules with the surface of the TiO₂. The latter may lead to enhance sensor specificity/selectivity.

1-28. (canceled)

29. A field-effect transistor comprising:
a source region;
a drain region;
a semiconductor layer disposed between the source and drain regions;
a gate region; and
a dielectric region disposed between the semiconductor layer and the gate
wherein the semiconductor layer comprises a titanium dioxide film.

30. The transistor as claimed in claim 29, wherein the semiconductor layer is made substantially entirely of titanium dioxide.

31. The transistor as claimed in claim 29, wherein the semiconductor layer is substantially dense.

32. The transistor as claimed in claim 29, wherein the semiconductor layer is mesoporous.

33. The transistor as claimed in claim 29, wherein the semiconductor layer is a combination of both substantially dense and mesoporous titanium dioxide.

34. The transistor as claimed in claim 29, fabricated on a flexible substrate.

35. The transistor as claimed in claim 29, further comprising an organic dye/semiconductor layer disposed adjacent to the titanium dioxide semiconductor layer.

36. The transistor as claimed in claim 35, wherein the organic dye/semiconductor layer further comprises titanium dioxide.

37. The transistor as claimed in claim 36, wherein the titanium dioxide within the organic dye/semiconductor layer is mesoporous.

38. The transistor as claimed in claim 32, wherein the mesoporous semiconductor layer is coated with a layer of dye molecules to act as an optical sensitizer.

39. The transistor as claimed in claim 32, wherein the mesoporous semiconductor layer is infiltrated with a molecular hole transporting organic semiconductor.

40. The transistor as claimed in claim 29, being a light-sensing field-effect transistor.

41. The transistor as claimed in claim 29, wherein the semiconductor layer further comprises molecular adsorbates.

42. The transistor as claimed in claim 41, wherein the molecular adsorbates comprise at least one of dye pigments and protein molecules.

43. The transistor as claimed in claim 41, adapted to sense at least one of gas and biological molecules.

44. The transistor as claimed in claim 43, further comprising receptors on a surface of the semiconductor layer to enhance reaction between the semiconductor layer and the at least one of the gas and biological molecules.

45. A display comprising the transistor as claimed in claim 29.

46. A sensor comprising the transistor as claimed in claim 29.

47. A method of forming a field-effect transistor comprising the steps of:
forming a dielectric layer adjacent a gate;
forming a source region and a drain region; and
forming a semiconductor layer on the dielectric layer, and comprising the semiconductor layer of titanium dioxide.

48. The method as claimed in claim 47, and depositing the semiconductor layer using a solution processing technique.

49. The method as claimed in claim 48, and depositing the semiconductor layer by spray pyrolysis.

50. The method as claimed in claim 49, and depositing the semiconductor layer using a precursor solution.

51. The method as claimed in claim 50, and depositing the semiconductor layer in a pulsed manner.

52. The method as claimed in claim 50, further comprising heat treating the semiconductor layer to remove residual un-reacted precursor solution.

53. The method as claimed in claim 48, and depositing the semiconductor layer by one of spin coating, doctor-blading and screen-printing a TiO₂ paste.

54. The method as claimed in claim 53, and depositing the semiconductor layer using a sol-gel colloidal suspension.
